(19) United States
(12) Patent Application Publication
(10) Pub. No.: US 2008/0232418 A1
(43) Pub. Date: Sep. 25, 2008

(54) Surface Emitting Laser

(75) Inventor: Takayoshi Anan, Tokyo (JP)

Correspondence Address: FOLEY AND LARDNER LLP;SUITE 500, 3000 K STREET NW, WASHINGTON, DC, 20007, US

(73) Assignee: NEC CORPORATION

(21) Appl. No.: 10/585,633

(22) PCT Filed: Jan. 24, 2005
(86) PCT No.: PCT/JP2005/000842

§ 371 Date: Jul. 11, 2006

(30) Foreign Application Priority Data
Jan. 23, 2004 (JP) 2004-016004

(51) Int. Cl. H01S 5/125

(52) U.S. Cl. 372/50.11

(57) ABSTRACT

A surface emitting laser includes a substrate, a first Bragg reflector layer formed on the substrate, an active layer formed on the first Bragg reflector layer and having a light-emitting region, a second Bragg reflector layer formed on the active layer to emit light from the surface in the direction of the optical axis (Z), and a light-scattering member for extracting light from the surface of the second Bragg reflector layer in a direction intersecting the optical axis. With this arrangement, the intensity of light emitted from the surface emitting laser in one direction can be monitored by a simple structure.

### TECHNICAL FIELD

The present invention relates to a vertical cavity surface emitting laser which outputs fundamental transverse mode light.

### BACKGROUND ART

Compared to an edge laser, a vertical cavity surface emitting laser (VCSEL: to be abbreviated as a VCSEL hereinafter) has many advantages such as a low manufacturing cost, a high manufacturing yield, and the ease of the formation of a secondary array, and hence is extensively developed in recent years.

As a surface emitting laser, a high-output, single fundamental transverse mode laser is demanded. To obtain a single fundamental transverse mode in an oxidized current confinement type surface emitting laser, however, the current confinement region must be decreased to about 5 μmφ or less. When the current confinement region is thus decreased, both the element resistance and heat resistance increase, so no sufficient output can be obtained any longer due to the influence of the generated heat.

In contrast to this, as one method of obtaining the necessary single mode optical output, a surface emitting laser having a structure in which no higher-order mode easily oscillates even if the size of the current confinement region is increased to some extent is disclosed.

The transverse mode of the VCSEL is such that when the current value is small, the VCSEL oscillates in a fundamental transverse mode in which the emission intensity is highest in the central portion, but if the current value is further increased, a higher-order transverse mode having a distribution in which the emission intensity is high in the peripheral portion appears. To obtain a high optical output while the fundamental transverse mode oscillation is maintained, therefore, it is effective to produce conditions under which no oscillation easily occurs in the peripheral portion in which the emission intensity of the higher-order transverse mode is high.

The conventional methods of realizing this state are roughly classified into two types of known techniques. One is an absorption loss control structure in which the light absorption loss in the peripheral portion of a reflecting mirror (Distributed Bragg Reflector: DBR) forming the cavity is increased, and the gain necessary for higher-order mode oscillation is increased, thereby preventing easy oscillation. The other is a reflection loss control structure in which a structure which decreases the reflectance itself without changing the absorption loss of the DBR is formed in the peripheral portion, thereby preventing easy occurrence of higher-order mode oscillation.

As the prior art of the absorption loss control structure, there is a technique which suppresses the occurrence of the higher-order transverse mode by increasing the carrier absorption by forming a p-type diffusion region of Zn in the peripheral portion (e.g., Japanese Patent No. 2876814 (reference 1)). There is also a technique which suppresses the occurrence of the higher-order transverse mode by increasing the absorption loss by a metal in an electrode contact portion of the peripheral portion (e.g., Japanese Patent Laid-Open No. 2000-332355 (reference 2)).

As the prior art of the reflection loss control structure, there is a technique which suppresses the occurrence of the higher-order transverse mode by forming a dielectric film on the uppermost surface in the stacking direction of the peripheral portion to form a so-called anti-reflection (AR) coat, thereby decreasing the reflectance of the DBR in the peripheral portion (e.g., Japanese Patent Laid-Open No. 2000-022271 (reference 3)). There is also a technique which suppresses the occurrence of the higher-order transverse mode by oxidizing an AlAs layer in a portion of the DBR in the peripheral portion to form an oxide film phase adjusting layer and make the DBR center wavelengths in the peripheral portion and central portion different from each other, thereby practically decreasing the reflectance of the DBR in the peripheral portion (e.g., Japanese Patent Laid-Open No. 2002-353562 (reference 4)).

In addition, there are techniques combining the above two techniques, in which the carrier absorption is increased by heavily doping a dopant in the peripheral portion as in reference 1, and at the same time the reflectance of the DBR is decreased by causing interdiffusion of elements forming the DBR by thermal annealing (e.g., Japanese Patent Laid-Open No. 2003-124570 (reference 5) and Japanese Utility Model Registration No. 3091855 (reference 6)).

### DISCLOSURE OF INVENTION

### Problems to be Solved by the Invention

When a light-emitting element is to be used in a system, the light-emitting element is in many cases so controlled as to hold the average emission intensity of the light-emitting element constant. In the case of an edge laser, light is emitted from the two end faces, so the average emission intensity of the light-emitting element can be held constant by control by monitoring the emission intensity of light emitted from one end face.

By contrast, the VCSEL basically has a structure which emits light in only one direction. Since the emitted light is coupled with an optical fiber, the emission intensity of the VCSEL is difficult to monitor. The emission intensity of the VCSEL is monitored by splitting the emitted light by a half mirror or the like. In this case, however, it is difficult to completely eliminate the return of the emitted light to the VCSEL, and this causes fluctuations in oscillation intensity.

It is an object of the present invention to make it possible to monitor the intensity of light emitted in one direction from a surface emitting laser with a simple structure.

It is another object to suppress the higher-order transverse mode oscillation of a surface emitting laser.

### Means for Solving the Problems

To achieve the above objects, a surface emitting laser of the present invention is characterized by comprising a first-conductivity-type substrate, a first-conductivity-type first Bragg reflector layer formed on the first-conductivity-type substrate, an active layer formed on the first Bragg reflector layer and including a light-emitting region, a second-conductivity-type second Bragg reflector layer formed on the active layer and including a surface which emits light in an optical axis direction, and monitor light extracting means for extracting light from the surface of the second Bragg reflector in a direction intersecting the optical axis direction.

In this surface emitting laser, the monitor light extracting means can be light scattering means which is formed in a partial region of the surface of the second Bragg reflector and scatters emitted light.

Also, the second Bragg reflector layer can comprise, in a peripheral portion, a low-reflectance region whose reflectance is lower than a reflectance of a central portion.

### EFFECTS OF THE INVENTION

In the present invention, the intensity of light emitted in one direction from the surface emitting laser can be monitored by extracting light in a direction intersecting the optical axis direction. Also, since the light scattering means is formed on the surface of the second Bragg reflector, the monitor light can be extracted with a simple structure. In addition, the monitor light can be extracted while higher-order transverse mode oscillation is suppressed, by forming the light scattering means in the peripheral portion of the surface of the second Bragg reflector, and further forming the low-reflectance region in the peripheral portion of the second Bragg reflector layer.

### BRIEF DESCRIPTION OF DRAWINGS

FIG. 1 is a sectional view of a VCSEL apparatus, which explains an outline of an embodiment of the present invention;

FIG. 2 is a sectional view showing the arrangement of the VCSEL apparatus according to the embodiment of the present invention;

FIG. 3 is a sectional view of a VCSEL apparatus according to a first arrangement example of the present invention;

FIG. 4 is a sectional view of a VCSEL apparatus according to a second arrangement example of the present invention; and

FIG. 5 is a sectional view of a VCSEL apparatus according to a third arrangement example of the present invention.

### BEST MODE FOR CARRYING OUT THE INVENTION

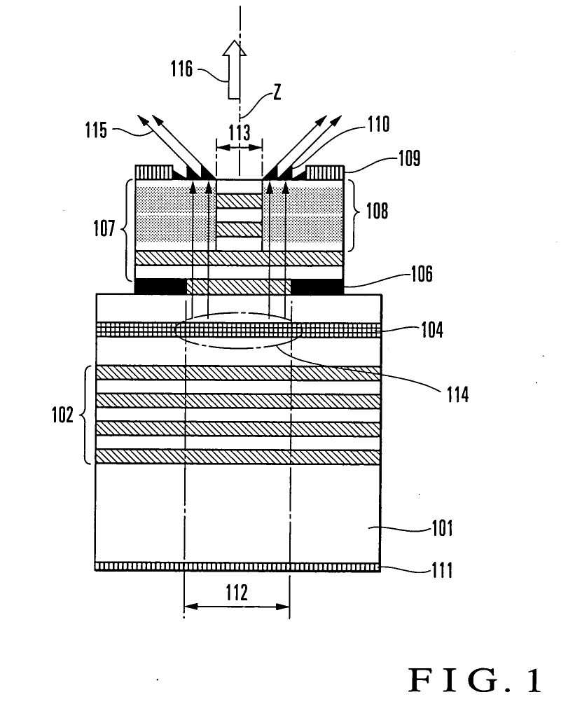

An outline of an embodiment of the present invention will be explained below with reference to FIG. 1.

A surface emitting laser (VCSEL) according to this embodiment comprises a stacked structure in which a first-conductivity-type first DBR layer 102, active layer 104, second-conductivity-type oxidized current confinement layer 106, and second-conductivity-type second DBR layer 107 are sequentially stacked on the surface of a first-conductivity-type substrate 101, a first electrode 109 formed on the surface (light-emitting surface) of the second DBR layer 107 and electrically connected to it, and a second electrode 111 formed on the lower surface of the substrate 101 and electrically connected to it.

One characteristic feature of this embodiment is that a light-scattering member 110 which scatters emitted light in a direction intersecting the direction of an optical axis Z is formed in the peripheral portion of the light-emitting surface of the second DBR layer 107. The light-scattering member 110 functions as a monitor light extracting means for extracting light emitted in the higher-order transverse mode to the outside as scattered light 115, thereby obtaining monitor light. A laser beam 116 emitted in the direction of the optical axis Z from the central portion of the light-emitting surface of the second DBR layer 107 is coupled with an optical fiber, and the scattered light 115 as the monitor light is detected by a photodetector placed close to this VCSEL. Therefore, the scattered light 115 is desirably scattered in directions which make as large angles as possible with the direction of the optical axis Z.

Also, in this embodiment, to suppress the occurrence of the higher-order transverse mode, a low-reflectance region 108 having reflectance lower than that of the central portion of emission of the second DBR layer 107 is formed outside (in the peripheral portion) of the central portion of emission. As a method of decreasing the reflectance, interdiffusion in a multilayered film forming the second DBR layer 107 can be used. Interdiffusion in a multilayered film is a phenomenon in which atoms forming the multilayered film diffuse to the individual layers. For example, a GaAs/AlAs multilayered film initially has a structure in which Ga and Al sharply change places with each other in the interface, but Ga and Al mix near the interface if interdiffusion occurs. For example, Al_{0.1}Ga_{0.9}As forms in the GaAs layer, and Al_{0.9}Ga_{0.1}As forms in the AlAs layer, so the reflectance starts lowering. When the interdiffusion is further advanced to completely mix Ga and Al, the GaAs layer changes to an Al_{0.5}Ga_{0.5}As layer, and the AlAs layer changes to an Al_{0.5}Ga_{0.5}As layer, if the thicknesses of these lasers are equal, so it becomes impossible to distinguish between them any longer. If this is the case, the multilayered film can no longer function as a multilayered reflecting film. Note that in the formation of the low-reflectance region 108, it is not always necessary to perform interdiffusion until the components of the individual layers become equal.

In the current confinement layer (current (confinement) aperture layer) 106, the electrical resistance in the peripheral portion is much higher than that in the central portion. The current confinement layer 106 is formed to allow an electric current to intensively flow into the central portion.

A width 113 of the central portion, in which the light-scattering member 110 is not formed, of the light-emitting surface of the second DBR layer 107 and a width (i.e., the aperture width of the low-reflectance region 108) 113 of the central portion of emission of the second DBR layer 107 are made smaller than a width (i.e., the aperture width of the current confinement layer 106) 112 of the central portion of the current confinement layer 106. A light-emitting region which emits light in the active layer 104 when an electric current is injected forms an elliptic region 114 in conformity with the aperture width 112 of the current confinement layer 106.

The light emitted from the elliptic light-emitting region 114 is fed back by an optical resonator formed by the first and second DBR layers 102 and 107, thereby causing laser oscillation. In this embodiment, however, the low-reflectance region 108 is formed in the second DBR layer 107, so no sufficient feedback occurs in the peripheral portion of emission. Accordingly, the laser oscillates in the fundamental transverse mode in which the central portion of emission has the highest light intensity, but hardly oscillates in the higher-order transverse mode in which the peripheral portion of emission has the highest light intensity.

Of the light in the higher-order transverse mode in which the peak of emission occurs in the peripheral portion, this peak portion of emission passes through the low-reflectance region 108. A large amount of light is transmitted through the VCSEL and output outside as the scattered light 115 in proportion to the decrease in reflectance of the low-reflectance region 108. In this embodiment, the scattered light 115 is used as an emission intensity monitor, and used to control the output of the laser beam 116 of the VCSEL.

With the above arrangement, light can be extracted from the peripheral portion of the light-emitting surface of the VCSEL, and used as an emission intensity monitor. It is also possible to suppress higher-order transverse mode oscillation.

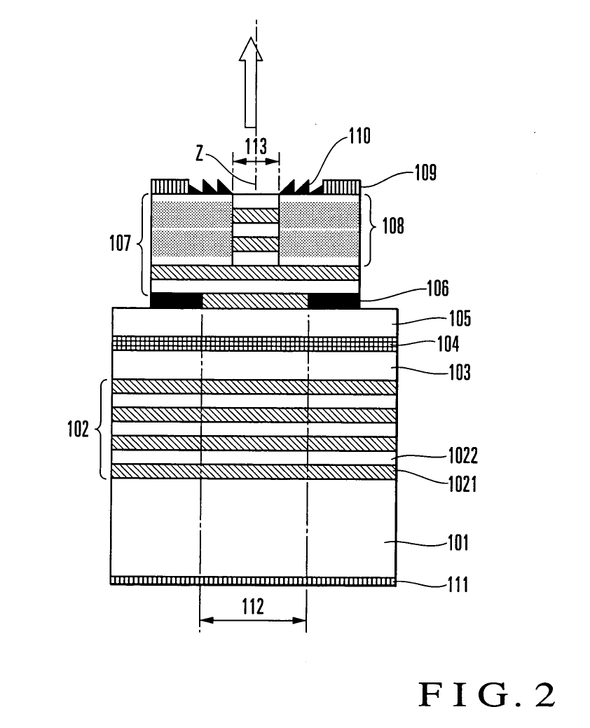

The arrangement of the VCSEL according to this embodiment will be explained in more detail below with reference to FIG. 2.

The VCSEL according to this embodiment comprises the multilayered structure in which the first-conductivity-type first DBR layer 102, a first-conductivity-type lower cladding layer 103, the active layer 104, a second-conductivity-type upper cladding layer 105, the second-conductivity-type oxidized current confinement layer 106, and the second-conductivity-type second DBR layer 107 are sequentially stacked on the surface of the first-conductivity-type substrate 101, the first electrode 109 formed on the surface (light-emitting surface) of the second DBR layer 107 and electrically connected to it, and the second electrode 111 formed on the lower surface of the substrate 101 and electrically connected to it.

Each of the first and second DBR layers 102 and 107 is made of a multilayered film including low-refractive-index layers 1021 and high-refractive-index layers 1022. The number of pairs of the low-refractive-index layers 1021 and high-refractive-index layers 1022 is normally set so that the number of pairs in the second DBR layer 107 is smaller than that in the first DBR layer, in order to make the reflectance of the second DBR layer 107 on the exit side lower than that of the first DBR layer 102.

The resonator is made of the lower cladding layer 103, active layer 104, and upper cladding layer 105. The active layer 104 is formed in a portion equivalent to the antinode of the field strength of the resonator. Especially when the high-resistance peripheral portion of the current confinement layer 106 is formed by an oxide film, the active layer 104 is formed in a portion equivalent to the node of the field strength of the resonator. The reason for this is to prevent the light confining effect from becoming too large, because the refractive index difference between the oxide film of the current confinement layer 106 and the semiconductor forming the resonator is large. Also, the aperture width 112 of the current confinement layer 106 has a close relation to the transverse mode of the VCSEL, and requires precise control.

In this embodiment, the light-scattering member 110 for extracting monitor light outside is formed around the optical axis Z. The light-scattering member 110 preferably has a structure which scatters light toward the periphery. For example, a Fresnel lens can be used as the light-scattering member 110.

In addition, to increase the monitor light extraction efficiency, the low-reflectance region 108 having reflectance lower than that of the central portion of emission of the second DBR layer 107 is formed outside (in the peripheral portion) of the central portion of emission. The low-reflectance region 108 has the same central axis as the current confinement layer 106, and the inner diameter (aperture width) 113 surrounded by the low-reflectance region 108 is smaller than the aperture width 112 of the current confinement layer 106. The low-reflectance region 108 is formed by interdiffusion between the multilayered films forming the second DBR layer 107.

The operation of the VCSEL according to this embodiment will be explained below.

Around the optical axis Z, the light-scattering member 110 which scatters exit light is formed in the peripheral portion near the surface of the second DBR layer 107. This makes the reflectance of this portion lower than that of the central portion. The fundamental transverse mode has a high-field-strength portion in the central portion, and the higher-order transverse mode has a high-field-strength portion in the peripheral portion. Since the light-scattering member 110 is formed in the peripheral portion of the light-emitting surface, higher-order transverse mode oscillation is suppressed, and fundamental transverse mode oscillation continues.

The aperture width 112 of the current confinement layer 106 is larger than the width (the aperture width of the light-scattering member 110) 113 of the region, in which the light-scattering member 110 is not formed, of the light-emitting surface of the second DBR layer 107. Accordingly, the light-emitting region in the active layer 104 is wider than the aperture width 113 of the light-scattering member 110. Consequently, a considerable amount of light is generated in the peripheral portion of the light-emitting surface where the light-scattering member 110 which scatters exit light is formed, although the higher-order transverse mode does not reach the gain necessary for oscillation. This light is filtered in respect of wavelength when passing through the second DBR layer 107. By resonation with the first DBR layer 102, only light having a wavelength near the oscillation wavelength of the VCSEL is output outside through the light-scattering member 110. This light output outside is the scattered light 115. The scattered light 115 is preferably efficiently extracted outside as the monitor light, and the scattered light 115 preferably deviates as far as possible toward the outer periphery from the optical axis Z of the laser.

If it is difficult to suppress the higher-order transverse mode only with the light-scattering member 110, as shown in FIG. 2, the low-reflectance region 108 having a low reflectance is formed in the peripheral portion of the second DBR layer 107. This makes higher-order transverse mode oscillation more difficult.

Also, the higher-order transverse mode light generated in the peripheral portion passes through the low-reflectance region 108, a large amount of light is output outside as the scattered light 115 in proportion to the decrease in reflectance in the low-reflectance region 108.

In this case, the spectrum of light transmitted through the second DBR layer 107 is broad, and close to the electroluminescence of the active layer 104. This is so because the existence of the low-reflectance region 108 decreases the stop bandwidth of the second DBR layer 07, and simultaneously lowers the highest reflectance over the entire stop bandwidth. As described above, the output light from the light-scattering member 110 has a wide spectrum and a high integral strength, and can be monitored outside.

As a method of lowering the reflectance in the low-reflectance region 108, interdiffusion between the multilayered films forming the second DBR layer 107 is used. For example, in a DBR film made of 24-pairs GaAs/AlAs, the light transmittance is 1% or less (the reflectance is 99% or more). In contrast to this, electron beam irradiation is performed in only the peripheral portion so that no interdiffusion occurs in the DBR in the central portion of emission, and abnormal diffusion in the region where this electron beam irradiation is performed is used to cause interdiffusion in the multilayered film. When the DBR film is thus changed to a DBR of AlGaAs(Al:0.4)/AlGaAs(Al:0.6), the transmittance rises to about 23% (i.e., the reflectance lowers to 77%).

When the reflectance in the low-reflectance region 108 is to be decreased, if interdiffusion is performed by impurity diffusion, carrier absorption also occurs. In the above example, if the absorption coefficient in each layer of the multilayered film is set at 100 cm⁻¹, the absorbance in the second DBR layer 107 as a whole is about 4%, and the reflectance decreases to about 74% accordingly. However, the transmittance is about 22%, i.e., has not changed much from that when there is no carrier absorption.

Accordingly, interdiffusion by an impurity lowers the reflectance of the second DBR layer 107, but has no large effect on the transmittance. This makes interdiffusion by an impurity effective because the higher-order transverse mode is suppressed, but the amount of monitor light output outside through the VCSEL is larger than that in a normal case.

This embodiment has been explained by assuming that the first conductivity type is an n-type and the second conductivity type is a p-type, but the effects are the same even in the opposite case. In this case, however, the current confinement layer 106 is inserted between the first DBR layer 102 and the active layer 104. The current confinement layer 106 may also be inserted into the second DBR film 107.

Practical arrangement examples of the VCSEL according to this embodiment will be explained below.

### FIRST ARRANGEMENT EXAMPLE

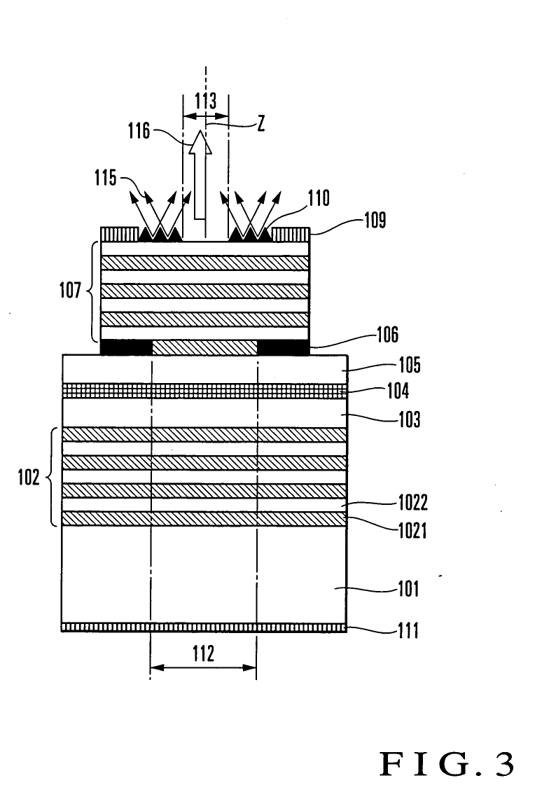

A VCSEL according to a first arrangement example will be explained with reference to FIG. 3. Note that the following explanation is an example of a short-wavelength laser apparatus, and a material having an oscillation wavelength of about 0.85 μm is selected.

First, as shown in FIG. 3, a first DBR layer 102 formed by stacking a plurality of n-type DBR layers (n-type semiconductor mirror layers) having a pair of an n-type Al_{0.2}Ga_{0.8}As layer 1022 and n-type Al_{0.9}Ga_{0.1}As layer
as a basic unit, a lower cladding layer 103 made of n-type Al_{0.3}Ga_{0.7}As, an active layer 104 made of an undoped GaAs quantum well and Al_{0.2}Ga_{0.8}As barrier layer, an upper cladding layer 105 made of p-type Al_{0.3}Ga_{0.7}As, an oxidized current confinement layer 106 made of p-type AlₓGa₁₋ₓAs (0.9≦x≦1), a second DBR layer 107 formed by stacking a plurality of DBR layers (p-type semiconductor mirror layers) having a pair of a p-type Al_{0.2}Ga_{0.8}As layer and p-type Al_{0.9}Ga_{0.1}As layer as a basic unit, and Al_{y}Ga_{1-y}As (0.9≦y≦1) as the material of a light-scattering member 110 are sequentially stacked on an Si-doped n-type GaAs substrate 101 by a metal organic chemical vapor deposition (MOCVD) method. It is also possible to use another growth method such as a molecular beam epitaxy (MBE) method.

In each of the DBR layers 102 and 107, the film thickness of each of Al_{0.2}Ga_{0.8}As having a high refractive index and Al_{0.9}Ga_{0.1}As having a low refractive index is so set that the optical path length in each of these media is approximately ¼ of about 0.85 μm as the oscillation wavelength. It is also possible to set the total film thickness (the film thickness of each DBR) of the thickness of Al_{0.2}Ga_{0.8}As and that of Al_{0.9}Ga_{0.1}As such that the optical path length is ½ of about 0.85 μm as the oscillation wavelength.

Subsequently, the epitaxial growth film is coated with a photoresist to form a circular resist mask. Etching is then performed by dry etching until the surface of the upper cladding layer 105 is exposed, thereby forming a columnar structure about 30 μm in diameter. In this step, the circumferential surface of the current confinement layer 106 is exposed. After that, the resist mask is removed. Then, the Al_{y}Ga_{1-y}As layer as the mesa upper surface is coated with a photoresist again to form an annular resist mask concentrically with the mesa. The dimensions of this resist mask are an inner diameter of about 8 to 10 μm, and an outer diameter of about 12 to 14 μm. After that, etching is performed until the Al_{0.2}Ga_{0.8}As layer as the uppermost surface of the second DBR layer 107 is exposed, thereby forming an annular Al_{y}Ga_{1-y}As layer.

After that, heating is performed in an oven in a steam ambient at a temperature of about 400° C. for about 10 min. As a consequence, the current confinement layer 106 and the Al_{y}Ga_{1-y}As layer as the mesa uppermost surface are selectively oxidized into an annular shape at the same time. This oxidation forms an oxidized region in the peripheral portion of the current confinement layer 106, and an unoxidized region about 8 μm in diameter in the central portion. Also, the Al_{y}Ga_{1-y}As layer as the annular mesa uppermost surface partially changes to AlGaOₓ by the oxidation, but forms a light-scattering member 110 having an three-dimensional structure on its surface because the Al composition is large.

The current confinement layer 106 is formed to allow an electric current to intensively flow into the active layer region having substantially the same width as the unoxidized region.

After that, an annular first electrode 109 made of titanium (Ti)/gold (Au) is formed on the outer periphery of the mesa, and a second electrode 111 made of an AuGe alloy is formed on the entire lower surface of the substrate 101.

When the second DBR layers 107 were stacked by 24 pairs, the reflectance in a portion having no light-scattering member 110 was about 99.8%, and the reflectance in a portion having the light-scattering member 110 is about 99%, i.e., a reflectance decrease capable of suppressing the higher-order transverse mode was obtained. In addition, since the aperture diameter of the current confinement layer 106 can be increased to 8 μm, it is possible to reduce the electrical resistance, and suppress the operating voltage to about 3 V or less. This makes a high-output operation of about 3 mW or more possible while the single fundamental mode is maintained.

Also, not only the output of a laser 113 but also scattered light 115 from the light-scattering member 110 can be observed from a near field image of this laser. The scattered light 115 can be used as monitor light of the laser.

### SECOND ARRANGEMENT EXAMPLE

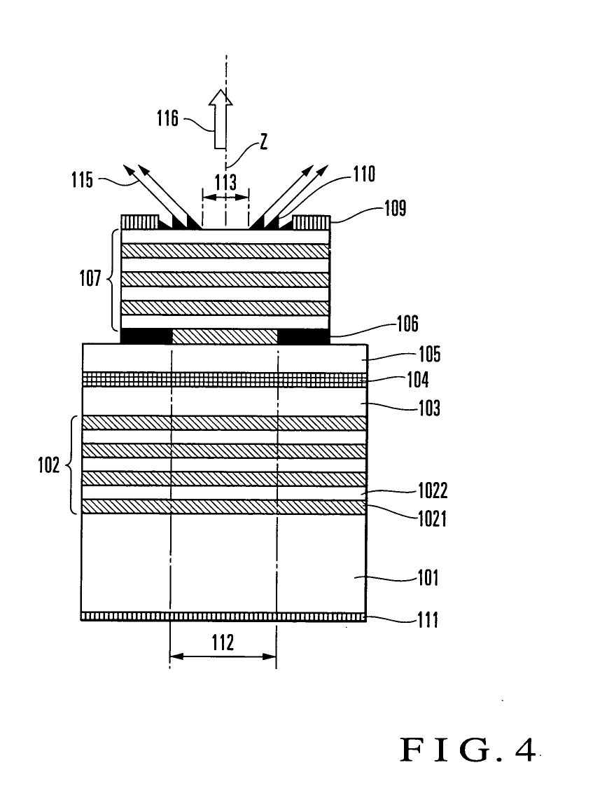

A VCSEL according to a second arrangement example will be explained below with reference to FIG. 4.

The difference from the first arrangement example shown in FIG. 3 is that a light-scattering member 110 is not a simple scattering member but emits monitor light in only the direction away from an optical axis Z.

In this arrangement example, the light-scattering member 110 has the structure of a Fresnel lens.

To form a Fresnel lens, a material which can be selectively etched and has a hardly oxidizable surface is favorable. The layer structure up to a second DBR layer 107 is the same as the first embodiment, but a λ/2 layer of GaAs is finally stacked, instead of the Al_{y}Ga_{1-y}As layer, on the second DBR layer 107.

Note that the uppermost layer need not be the GaAs layer as long as the layer has a film thickness of λ/2 and is made of a material which can be selectively etched and has a hardly oxidizable surface. An example is an In_{0.5}Ga_{0.5}P layer.

A Fresnel lens can be manufactured by the conventional method of patterning the shape of a photoresist by electron beam exposure, and transferring the patterned photoresist by dry etching. The ring pitch of the Fresnel lens was set to 0.5 μm, and the lens was inclined at about 15° so that the film thickness increased toward the circumference of the circle. Accordingly, light rising substantially perpendicularly to the substrate surface is output to make an angle of about 40° with the substrate surface.

Since the light-scattering member 110 suppresses higher-order transverse mode oscillation, a high-output operation of about 3 mW or more can be performed while the single fundamental mode is maintained, and it is found by observation of a near field image that the monitor light is concentrically output to make an angle of about 50° with the optical axis Z.

### THIRD ARRANGEMENT EXAMPLE

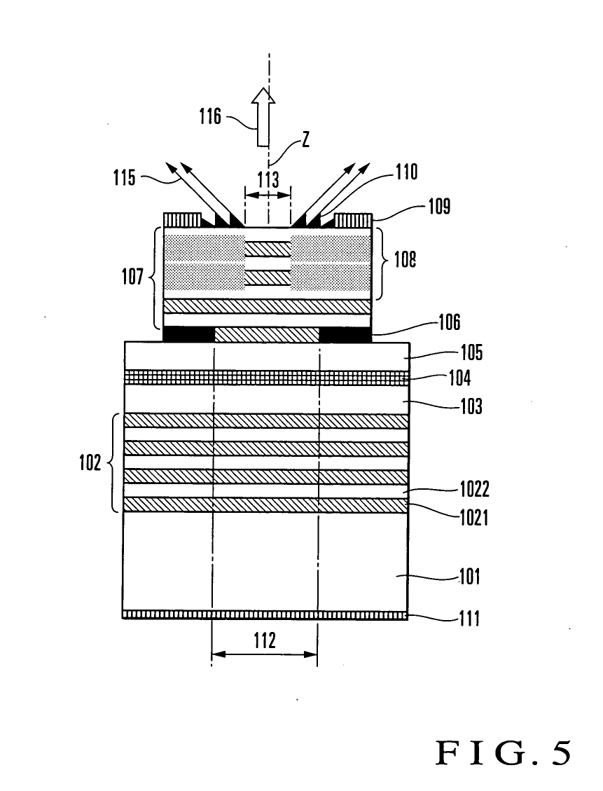

A VCSEL according to a third arrangement example will be explained below with reference to FIG. 5.

The difference from the second arrangement example shown in FIG. 4 is that a low-reflectance layer 108 having reflectance lower than that of the central portion of emission is formed in the peripheral portion of a second DBR layer 107.

In this arrangement example, an annular ZnO film is formed by sputtering on the uppermost GaAs λ/2 layer serving as a light-scattering member 110, and annealing is performed at 580° C. for 10 min. As a consequence, Zn interdiffusion occurs to a depth of about 2 μm in the peripheral portion except for the central portion of an optical axis Z. This forms a moderate interface between the Al_{0.2}Ga_{0.8}As layer having a high refractive index and the Al_{0.9}Ga_{0.1}As layer having a low refractive index, thereby lowering the reflectance in this region. Accordingly, the single fundamental mode is maintained even when an aperture width 113 of the interdiffusion region, i.e., the low-reflectance region 108 is as large as 6 μm, so a high-output operation of about 5 mW or more is possible.

In addition, while the reflectance of the DBR lowers by interdiffusion, the transmittance rises, and the amount of scattered light 115 from the light-scattering member 110 also increases.

Although undoped GaAs or undoped Al_{0.2}Ga_{0.8}As is used as the material of the active layer 104 in the above arrangement examples, the present invention is not limited to these materials, and it is also possible to form a near infrared VCSEL by using GaAs or InGaAs, and apply the present invention to a visible VCSEL such as InGaP or AlGaInP.

Furthermore, long-waveband single-mode VCSELs may also be formed by using InGaAsP on an InP substrate and GaInNAs, GaInNAsSb, and GaAsSb on a GaAs substrate. These VCSELs are very effective in relatively long distance communications using single-mode fibers. In addition, a blue or ultraviolet VCSEL can be formed by using a GaN series or ZnSe series.

It is of course also possible, in accordance with these materials of the active layer 104, to appropriately select and set the materials and compositions of the other layers including the DBR layers 102 and 107, and the individual layer thicknesses including the frequencies of the DBR layers 102 and 107.

The current confinement layer 106 is formed by oxidizing aluminum (Al) in the VCSELs according to the first to third arrangement examples, but the material is not limited to Al, and it is also possible to use any material by which the oxidized region largely increases the electrical resistance (desirably forms an insulator) compared to the unoxidized region.

Since the shapes of the light-scattering member 110 and low-reflectance region 108 are annular in the first to third arrangement examples, the section of the output laser beam 116 is also annular, but it is also possible, where necessary, to emit the output laser beam 116 having a desired sectional shape such as an ellipse.

The present invention is not limited to the practical arrangements and methods described above, and variations can be made without departing from the spirit and scope of the invention.

1. A surface emitting laser comprising:
a substrate;
a first Bragg reflector layer formed on said substrate;
an active layer formed on the first Bragg reflector layer and including a light-emitting region;
a second Bragg reflector layer formed on said active layer and including a surface which emits light in an optical axis direction; and
monitor light extracting means for extracting light from the surface of said second Bragg reflector in a direction intersecting the optical axis direction.

2. A surface emitting laser according to claim 1, wherein said monitor light extracting means comprises light scattering means which is formed in a partial region of the surface of said second Bragg reflector and scatters emitted light.

3. A surface emitting laser according to claim 2, wherein said light scattering means is formed in a peripheral portion of the surface of said second Bragg reflector.

4. A surface emitting laser according to claim 2, wherein said light scattering means emits light from the surface of said second Bragg reflector in only a direction intersecting the optical axis direction.

5. A surface emitting laser according to claim 2, wherein said light scattering means comprises a Fresnel lens.

6. A surface emitting laser according to claim 3, wherein a width of a central portion of the surface of said second Bragg reflector layer where said light scattering means is not formed is smaller than a width of the light-emitting region of said active layer.

7. A surface emitting laser according to claim 3, further comprising a current confinement layer which is formed in one of a portion between said first Bragg reflector layer and said active layer, a portion between said second Bragg reflector layer and said active layer, and a portion in said second Bragg reflector layer, and in which an electrical resistance of a central portion is lower than an electrical resistance of a peripheral portion.

8. A surface emitting laser according to claim 7, wherein a width of a central portion of the surface of said second Bragg reflector layer where said light scattering means is not formed is smaller than an aperture width of said current confinement layer.

9. A surface emitting laser according to claim 3, wherein the light extracted by said monitor light extracting means is light obtained by suppressing higher-order transverse mode oscillation.

10. A surface emitting laser according to claim 9, wherein said second Bragg reflector layer comprises, in a peripheral portion, a low-reflectance region whose reflectance is lower than a reflectance of a central portion.

11. A surface emitting laser according to claim 10, wherein
said second Bragg reflector layer comprises a multilayered structure including a plurality of films, and
said low-reflectance region is formed by interdiffusion between said plurality of films.

12. A surface emitting laser according to claim 11, wherein said low-reflectance region is formed by impurity diffusion.

13. A surface emitting laser according to claim 1, further comprising:
a first electrode electrically connected to said second Bragg reflector layer; and
a second electrode electrically connected to said substrate.
